(19) United States
(12) Patent Application Publication
(10) Pub. No.: US 2017/0263299 A1
(43) Pub. Date: Sep. 14, 2017

(54) SEMICONDUCTOR MEMORY DEVICE

(71) Applicant: KABUSHIKI KAISHA TOSHIBA, Tokyo (JP)

(72) Inventor: Ryousuke TAKIZAWA, Naka Kanagawa (JP)

(73) Assignee: KABUSHIKI KAISHA TOSHIBA, Tokyo (JP)

(21) Appl. No.: 15/265,787

(22) Filed: Sep. 14, 2016

Related U.S. Application Data
(60) Provisional application No. 62/307,171, filed on Mar. 11, 2016.

(51) Int. Cl. G11C 11/16

(52) U.S. Cl. CPC G11C 11/1675; G11C 11/1673; G11C 11/1697

(57) ABSTRACT

According to one embodiment, a semiconductor memory device includes a memory cell and a first circuit. The memory cell includes a variable resistance element. The first circuit performs writing for the memory cell. The first circuit starts writing first data before it receives write data including the first data and second data, and starts writing the second data after it receives the write data.

### CROSS-REFERENCE TO RELATED APPLICATIONS

This application claims the benefit of U.S. Provisional Application No. 62/307,171, filed Mar. 11, 2016, the entire contents of which are incorporated herein by reference.

### FIELD

Embodiments described herein relate generally to a semiconductor memory device.

### BACKGROUND

A semiconductor memory device that utilizes a magnetoresistive effect is known in the art.

### BRIEF DESCRIPTION OF THE DRAWINGS

FIG. 1 illustrates function blocks of a semiconductor memory device according to a first embodiment.

FIG. 2 illustrates a configuration of a cell array of the semiconductor memory device of the first embodiment.

FIGS. 3 and 4 illustrate a configuration of a write circuit including the cell array and write driver of the first embodiment.

FIG. 5 is a timing chart illustrating writing performed in the semiconductor memory device of the first embodiment.

FIG. 6 is a timing chart illustrating details of the writing performed in the semiconductor memory device of the first embodiment.

FIG. 7 illustrates how a write error rate and a write current are related in a semiconductor memory device.

FIG. 8 illustrates a configuration of a cell array of a semiconductor memory device according to a second embodiment.

FIGS. 9 and 10 illustrate a configuration of a write circuit including the cell array and write driver of the second embodiment.

FIG. 11 is a timing chart illustrating writing performed in the semiconductor memory device of the second embodiment.

FIG. 12 is a timing chart illustrating details of the writing performed in the semiconductor memory device of the second embodiment.

FIG. 13 illustrates function blocks of a semiconductor memory device according to a third embodiment.

FIGS. 14 and 15 illustrate a configuration of a write circuit including the cell array and write driver of the third embodiment.

FIGS. 16 and 17 illustrate how a write voltage varies by the temperature compensation in the foregoing embodiments.

FIG. 18 illustrates how a write voltage application time varies by the temperature compensation in the foregoing embodiments.

### DETAILED DESCRIPTION

Embodiments will be described with reference to the accompanying drawings. In the description below, structural elements having the same functions and configurations will be denoted by the same reference symbols. Each of the embodiments described below merely shows an exemplary apparatus and method that implement the technical ideas of the embodiments. The element materials, shapes, structures, arrangements etc. are not limited to those described below.

Each of the function blocks can be implemented in the form of hardware, computer software or a combination of them. The function blocks need not be those blocks described below. For example, part of the functions of one exemplary function block may be implemented by another function block. In addition, an exemplary function block may be divided into more specific function blocks.

In general, according to one embodiment, a semiconductor memory device comprises a memory cell and a first circuit. The memory cell includes a variable resistance element. The first circuit performs writing for the memory cell. The first circuit starts writing first data before it receives write data including the first data and second data, and starts writing the second data after it receives the write data.

### [1] First Embodiment

A semiconductor memory device according to the first embodiment will be described.

### [1-1] Configuration of Semiconductor Memory Device

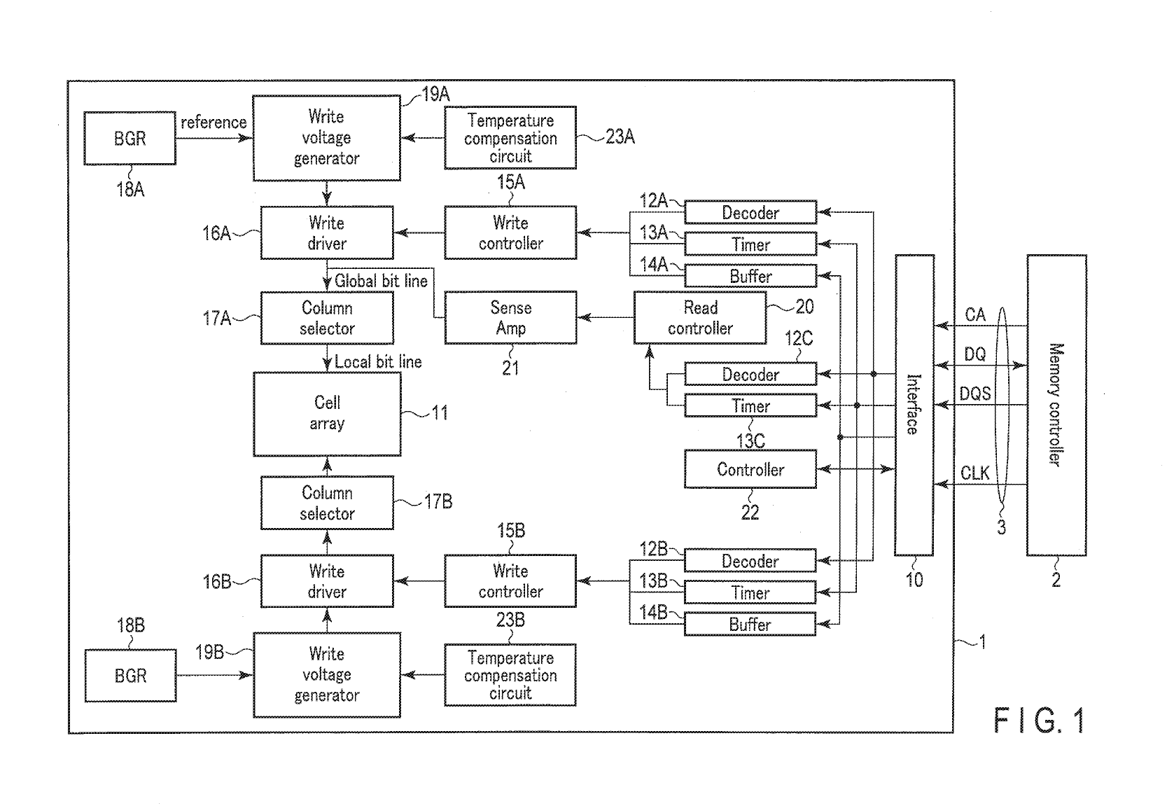

FIG. 1 illustrates function blocks of a semiconductor memory device according to the first embodiment and a memory controller. The semiconductor memory device 1 and the memory controller (or host device) 2 constitute a memory system. For example, the semiconductor memory device 1 can be a dynamic random access memory (DRAM), a magnetoresistive RAM (MRAM), a resistive RAM (ReRaM) or a phase change RAM (PCRAM). In the description below, reference will be made to the case where the semiconductor memory device 1 is an MRAM.

The semiconductor memory device 1 is connected to the memory controller 2 by connection lines 3. Through the connection lines 3, the semiconductor memory device 1 receives signal CA, data DQ, data strobe signal DQS, clocks CLK and a power supply voltage. Signal CA includes a command and an address signal. The address signal includes an address. At the time of reading, the semiconductor memory device 1 transmits data DQ to the memory controller 2 by way of the connection lines 3.

The memory controller 2 includes elements such as a central processing unit (CPU), a RAM, and a read only Memory (ROM), and controls the semiconductor memory device 1 by issuing commands.

The semiconductor memory device 1 includes an interface 10, a cell array 11 and a controller 22. The interface 10 controls the signal transmission between the semiconductor memory device 1 and the memory controller 2. The cell array 11 includes a plurality of memory cells MC. Each memory cell MC is connected to a bit line at the first end and connected to a source line at the second end. The cell array 11 will be described in detail later. The controller 22 controls the elements of the semiconductor memory device 1 and controls an operation performed thereby.

The semiconductor memory device 1 includes decoder 12A, timer 13A, buffer 14A, write controller 15A, write driver 16A, column selector 17A, band gap reference (BGR) circuit 18A, write voltage generator 19A and temperature compensation circuit 23A. These elements are used for driving the bit lines connected to the first end of each memory cell.

The semiconductor memory device 1 also includes decoder 12B, timer 13B, buffer 14B, write controller 15B, write driver 16B, column selector 17B, band gap reference circuit 18B, write voltage generator 19B and temperature compensation circuit 23B. These elements are used for driving the source bit lines connected to the second end of each memory cell.

The semiconductor memory device 1 further includes decoder 12C, timer 13C, a read controller 20 and a sense amplifier 21. An output of the sense amplifier 21 is supplied to column selector 17A.

The interface 10 is connected to decoders 12A, 12B and 12C, timers 13A, 13B and 13C, and buffers 14A and 14B. The interface 10 receives signals (a command and an address signal) from the memory controller 2 and supplies them to decoders 12A, 12B and 12C. Decoders 12A, 12B and 12C supply signals, which are based on the command and address signal, to write controller 15A, read controller 20 and write controller 15B, respectively. The interface 10 receives clocks CLK from the memory controller 2 and supplies them to timers 13A, 13B and 13C.

At the time of the writing, the interface 10 receives write data from the memory controller 2 and supplies it to decoders 12A and 12B and buffers 14A and 14B. Furthermore, the interface 10 supplies various control signals to the controller 22. The controller 22 controls the semiconductor memory device 1 based on the received control signals.

Decoders 12A, 12B and 12C select memory cells specified by an address signal they receive. More specifically, each decoder includes a row decoder and a column decoder. The row decoder selects a word line specified by the row address included in the address signal. The column decoder selects a bit line specified by the column address included in the address signal. The decoders 12 receive write data and outputs operation signals based on the write data.

Timers 13A, 13B and 13C receive clocks CLK and output various signals at timings based on the clocks CLK. To be specific, timers 13A and 13B output timer signals, used for controlling the driving times of write drivers 16A and 16B, based on instructions supplied from the controller 22. Timer 13C outputs a signal, used for controlling the sense amplifier 21, based on an instruction supplied from the controller 22. Buffers 14A and 14B temporarily store write data accompanying write commands.

Based on the address signal, write controllers 15A and 15B control the data write to the memory cells. To be more specific, write controllers 15A and 15B control write drivers 16A and 16B, based on the signals supplied from decoders 12A and 12B, timers 13A and 13B and buffer 14A and 14B, respectively.

Based on a column address, column selectors 17A and 17B select local bit lines (hereinafter referred to as bit lines) connected to a global bit line. In accordance with write data, write drivers 16A and 16B apply a driving voltage to the bit lines selected by the column selectors 17A and 17B. In accordance with a timer signal, write drivers 16A and 16B change the time in which the driving voltage is supplied to the bit lines.

Band gap reference circuits 18A and 18B supply a reference voltage, which is constant without reference to the temperature, to write voltage generators 19A and 19B. Based on the reference voltage, write voltage generators 19A and 19B generate a write voltage and supply it to write drivers 16A and 16B. Temperature compensation circuits 23A and 23B adjust the write voltage in accordance with the temperature of memory cell MC or ambient temperature of the semiconductor memory device 1. Temperature compensation circuits 23A and 23B will be described in more detail when the fourth embodiment is described.

When a read command is input, the read controller 20 controls the data read from a memory cell, based on an address signal. That is, the read controller 20 controls the sense amplifier 21, based on signals output from decoder 12C and timer 13C. The sense amplifier 21 senses a current flowing through a memory cell connected to the bit line selected by column selector 17A.

When a write command is input, the read controller 20 controls the sense amplifier 21, based on signals output from decoder 12C and timer 13C. The sense amplifier 21 applies a driving voltage to the bit line selected by column selector 17A. Such use of the read controller 20 and the sense amplifier 21 will be mentioned in connection with the third embodiment.

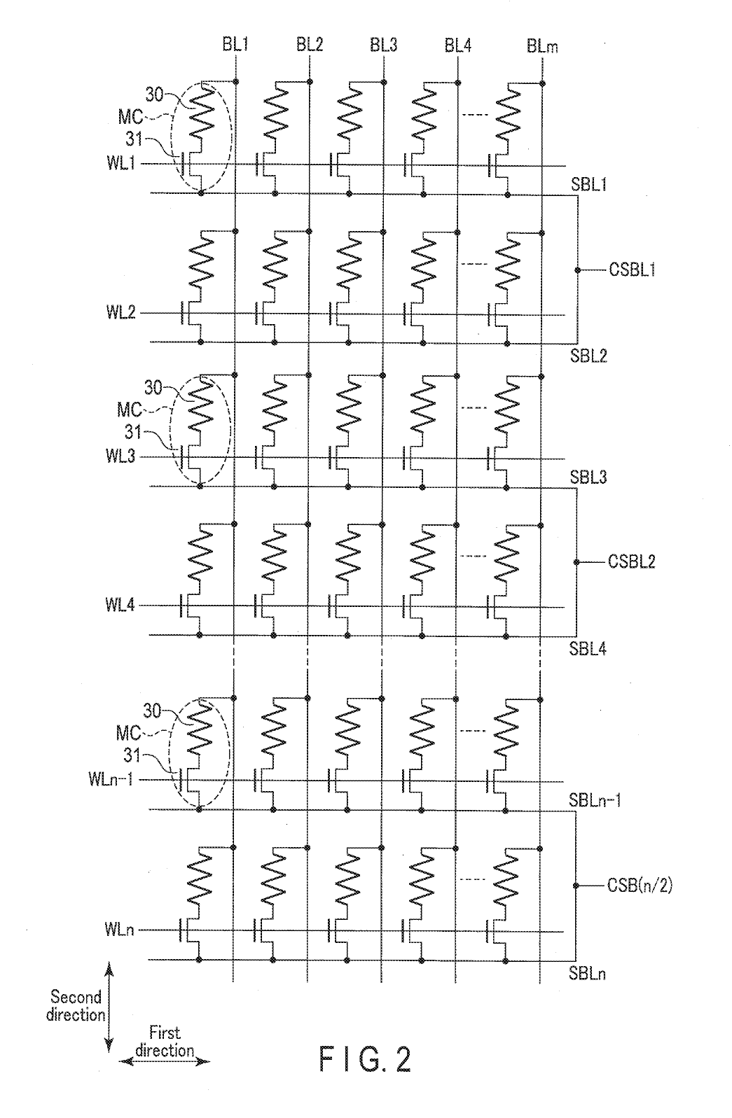

The cell array 11 of the semiconductor memory device 1 will be described in detail with reference to FIG. 2. FIG. 2 illustrates the elements and connections of the cell array 11. The cell array 11 includes a plurality of memory cells MC. Memory cells MC are arranged, for example, in a matrix pattern. Each memory cell MC retains data in a nonvolatile manner.

The cell array 11 comprises n word lines WL (WL1 to WLn), m bit lines BL (BL1 to BLm) and n source bit lines SBL (SBL1 to SBLn). The symbols n and m are natural numbers not less than 1.

The bit lines BL1, BL2, . . . , BLm are arranged in a first direction. The word lines WL1, WL2, . . . , WLn are arranged in a second direction so that they intersect the bit lines BL (for example, at right angles to each other). The source bit lines SBL1, SBL2, . . . , SBLn are also arranged in the second direction so that they intersect the bit lines BL (for example, at right angles to each other). Source bit lines SBL1 and SBL2 are connected to common source bit line CSBL1. Source bit lines SBL3 and SBL4 are connected to common source bit line CSBL2, and source bit lines SBLn−1 and SBLn are connected to common source bit line CSBL(n/2).

Memory cells MC of one row are connected to one word line WL and one source bit line SBL, and memory cells MC of one column are connected to one bit line BL. A memory cell MC is arranged at the position where word line WL and source bit line SB intersect bit line BL.

Each memory cell MC includes a variable resistance element, such as a magnetic tunnel junction (MTJ) element 30 and a selection transistor 31. The MTJ element 30 comprises an MTJ, and the MTJ includes two magnetic layers and a nonmagnetic layer located between the two magnetic layers. The two magnetic layers are a first magnetic layer (a reference layer) having a fixed direction of magnetization or magnetic anisotropy, and a second magnetic layer (a recording layer) having a variable direction of magnetization. The first magnetic layer having a fixed direction of magnetization means that the direction of magnetization is not inverted by the write current flowing through the MTJ element 30. Although the present embodiment will be explained referring to the case where the variable resistance element is an MTJ element, this is not restrictive. That is, the embodiment is applicable to a semiconductor memory device comprising elements that enable data to be recorded (retained) or read by application of a current or voltage, i.e., in response to a change in electric resistance, are applicable to a semiconductor memory device.

Where the directions of magnetization of the two magnetic layers are parallel, the MTJ element exhibits a minimal resistance value (a low-resistance state). Where the directions of magnetization of the two magnetic layers are antiparallel, the MTJ element exhibits a maximal resistance value (a high-resistance state). Two transition states showing these different resistances are assigned to binary data. When a write current flows from the first magnetic layer (reference layer) to the second magnetic layer (recording layer), the directions of magnetization of the two magnetic layers become antiparallel to each other. When a write current flows from the second magnetic layer to the first magnetic layer, the directions of magnetization of the two magnetic layers become parallel to each other.

The selection transistor 31 is an n-type metal oxide semiconductor field effect transistor (MOSFET), for example.

One end (a reference layer) of each MTJ element 30 is connected to bit line BL, and the other end (a recording layer) is connected to the drain (or source) of one selection transistor 31. The gate of each selection transistor 31 is connected to one word line WL, and the source (or the drain) thereof is connected to one source bit line SBL.

When one word line WL is made active by a read and write circuit, the selection transistor 31 connected to this word line WL is turned on. When the selection transistor 31 is turned on, the MTJ element 30 connected to the selection transistor 31 is connected to bit line BL and source bit line SBL. The memory cells MC connected to one word line WL belong to one row.

The memory cells connected to each bit line BL belong to one column. The cell array 11 includes m columns (column 1 to column m). A memory cell for which the writing or reading is performed is specified by the designation of a page address, that is, by the designation of a word line WL and a column. When the writing is performed, write data corresponding to one page and accompanying a write command is temporarily stored in buffers 14A and 14B. Part of the write data corresponding to one page is further specified by a column address. Thus, data which is part of the one-page data and is specified by the column address is written in one writing.

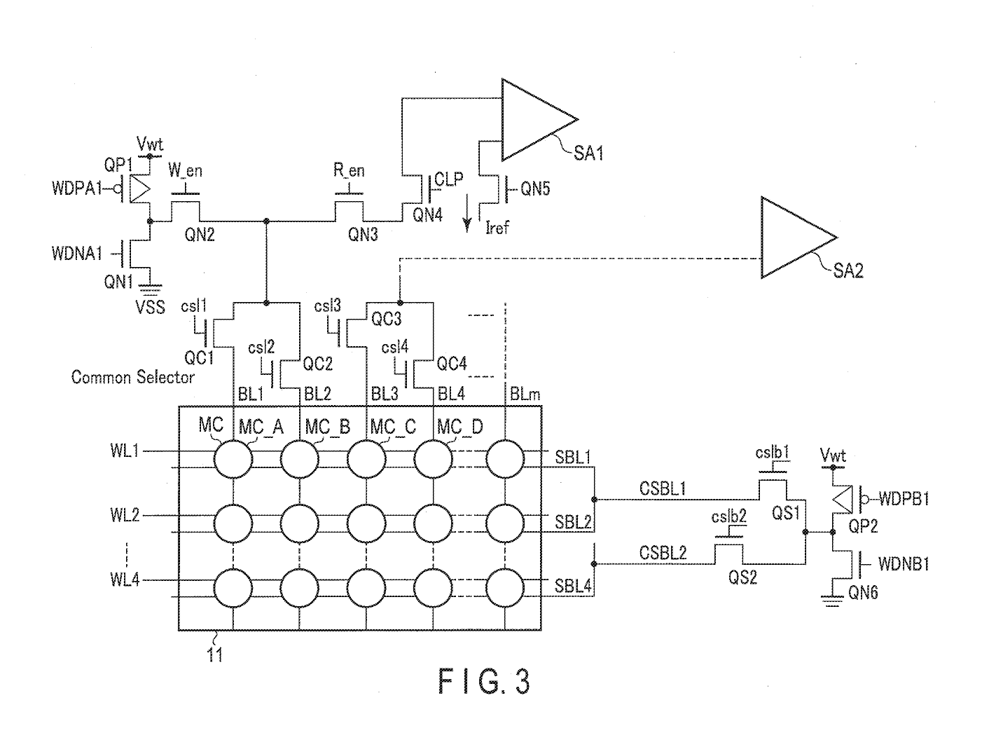

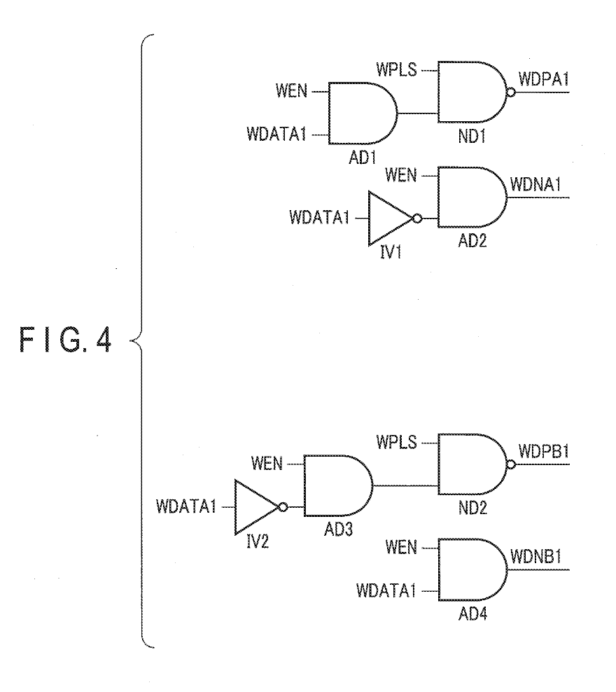

FIGS. 3 and 4 illustrate a configuration of a write circuit including the cell array and write driver of the first embodiment.

In the following, a description will be given of the elements and connections provided on the side of bit line BL.

As shown in FIG. 4, AND circuit AD1 receives write data WDATA1 accompanying a write command and a write enable signal WEN, and outputs write data WDATA1 when the write enable signal WEN is at high level (hereinafter referred to “H”). During the period when signal WPLS is “H”, NAND circuit ND1 outputs write data WDATA1 as signal WDPA1.

In the meantime, inverter IV1 receives write data WDATA1, and outputs an inverted signal obtained by inverting the received write data WDATA1. AND circuit AD2 receives the inverted signal and write enable signal WEN, and outputs the inverted signal as signal WDNA1 when the write enable signal WEN is at “H.”

As shown in FIG. 3, p-type metal oxide semiconductor field effect transistor (MOSFET) (hereinafter referred to a “pMOS transistor”) QP1 is supplied with signal WDPA1 at the gate and applied with write voltage Vwt at the source. N-type metal oxide semiconductor field effect transistor (MOSFET) (hereinafter referred to an “nMOS transistor”) QN1 is supplied with signal WDNA1 at the gate and applied with reference voltage VSS at the source. The drain of pMOS transistor QP1 and the drain of nMOS transistor QN1 are connected to each other.

The drains of pMOS transistor QP1 and nMOS transistor QN1 are connected, by way of nMOS transistor QN2, to either of the sources and drains of nMOS transistors QC1 and QC2. The other one of the source and drain of nMOS transistor QC1 is connected to bit line (or local bit line) BL1. The other one of the source and drain of nMOS transistor QC2 is connected to bit line BL2. Write enable signal W_en is supplied to the gate of nMOS transistor QN2. Column selection signals csl1 and csl2 are supplied to the gates of nMOS transistors QC1 and QC2, respectively.

The drain of nMOS transistor QN4 is connected to the first terminal of sense amplifier SA1, and the source of nMOS transistor QN4 is connected, by way of nMOS transistor QN3, to the sources or drains of nMOS transistors QC1 and QC2. Read enable signal R_en is supplied to the gate of nMOS transistor QN3, and clamp signal CLP is supplied to the gate of nMOS transistor QN4. The second terminal of sense amplifier SA1 is supplied with current Iref flowing through nMOS transistor QN5.

Bit lines BL3 and BL4 (and bit lines BLm−1 and BLm as well) have elements similar to bit lines BL1 and BL2 mentioned above, and are connected in a similar manner. NMOS transistors QC3 and QC4 are connected to bit lines BL3 and BL4, and column selection signals csl3 and csl4 are supplied to the gates of nMOS transistors QC3 and QC4, respectively. The same holds true of bit lines BLm−1 and BLm as well.

Next, a description will be given of the elements and connections provided on the side of source bit line SBL.

As shown in FIG. 4, inverter IV2 receives write data WDATA1, and outputs an inverted signal obtained by inverting the received write data WDATA1. AND circuit AD3 receives the inverted signal and write enable signal WEN, and outputs write data WDATA1 when the write enable signal WEN is at “H.” NAND circuit ND2 receives an output of AND circuit AD3 and signal WPLS, and outputs signal WDPB1.

AND circuit AD4 receives write data WDATA1 and write enable signal WEN, and outputs write data WDATA1 as signal WDNB1 when the write enable signal WEN is at “H.”

As shown in FIG. 3, pMOS transistor QP2 is supplied with signal WDPB1 at the gate and applied with write voltage Vwt at the source. NMOS transistor QN6 is supplied with signal WDNB1 at the gate and applied with reference voltage VSS at the source. The drain of pMOS transistor QP2 and the drain of nMOS transistor QN6 are connected to each other.

The drains of pMOS transistor QP2 and nMOS transistor QN6 are connected to either of the sources and drains of nMOS transistors QS1 and QS2. The other one of the source and drain of nMOS transistor QS1 is connected to common source bit line CSBL1. The other one of the source and drain of nMOS transistor QS2 is connected to common source bit line CSBL2. Common source bit line CSBL1 is connected to source bit lines SBL1 and SBL2. Common source bit line CSBL2 is connected to source bit lines SBL3 and SBL4. Column selection signals cslb1 and cslb2 are supplied to the gates of nMOS transistors QS1 and QS2, respectively.

### [1-2] Write Operation of Semiconductor Memory Device

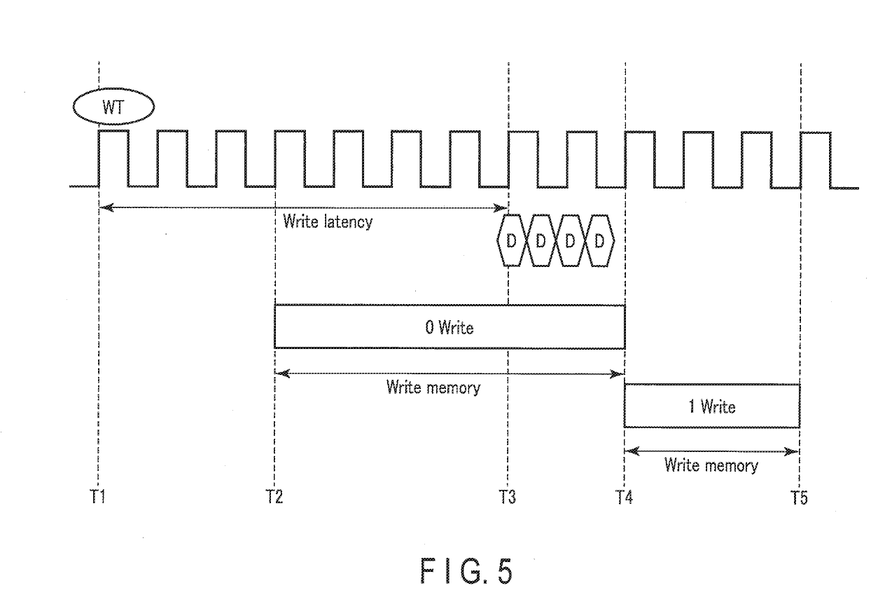

An outline of a write operation performed in the first embodiment will be described with reference to FIG. 5. FIG. 5 is a timing chart illustrating the writing performed in the semiconductor memory device of the first embodiment.

After the reception of write command WT at time T1, the semiconductor memory device 1 is kept on standby for write latency (corresponding to seven clocks), and receives write data accompanying the write command at time T3. The write latency (corresponding to seven clocks) is an example and varies in accordance with a clock frequency.

At time T2, which is after the reception of the write command WT at time T1 and before the reception of the write data at time T3, the writing of 0 data is started. The writing of 0 data is ended before the writing of 1 data is started at time T4 or substantially at the same time as the start of the write operation of 1 data. For example, the writing of 0 data is started immediately after the reception of the write command WT at time T1, or at time T2 which is 3 clocks after the reception of the write command WT. The writing of 0 data is ended after all the write data is received at time T4.

Alternatively, the writing of 1 data is started after all the write data is received. Thereafter, at time T5, the writing of 1 data is ended.

In the writing of 0 data, 0 data is written in all the memory cells MC designated by an address received along with a write command WT. In the writing of 1 data, 1 data is written only in the memory cells MC where it should be written, based on the received write data.

The “0 data” is intended to refer to the case where an MTJ element of the memory cell MC is in a low resistance state, and the “writing of 0 data” (which may be referred to as “0 writing” as well) is intended to refer to the writing by which an MTJ element of memory cell transitions from a high resistance state to a low resistance state. The “1 data” is intended to refer to the case where an MTJ element of the memory cell MC is in a high resistance state, and the “writing of 1 data” (which may be referred to as “1 writing” as well) is intended to refer to the writing by which the MTJ element transitions from a low resistance state to a high resistance state.

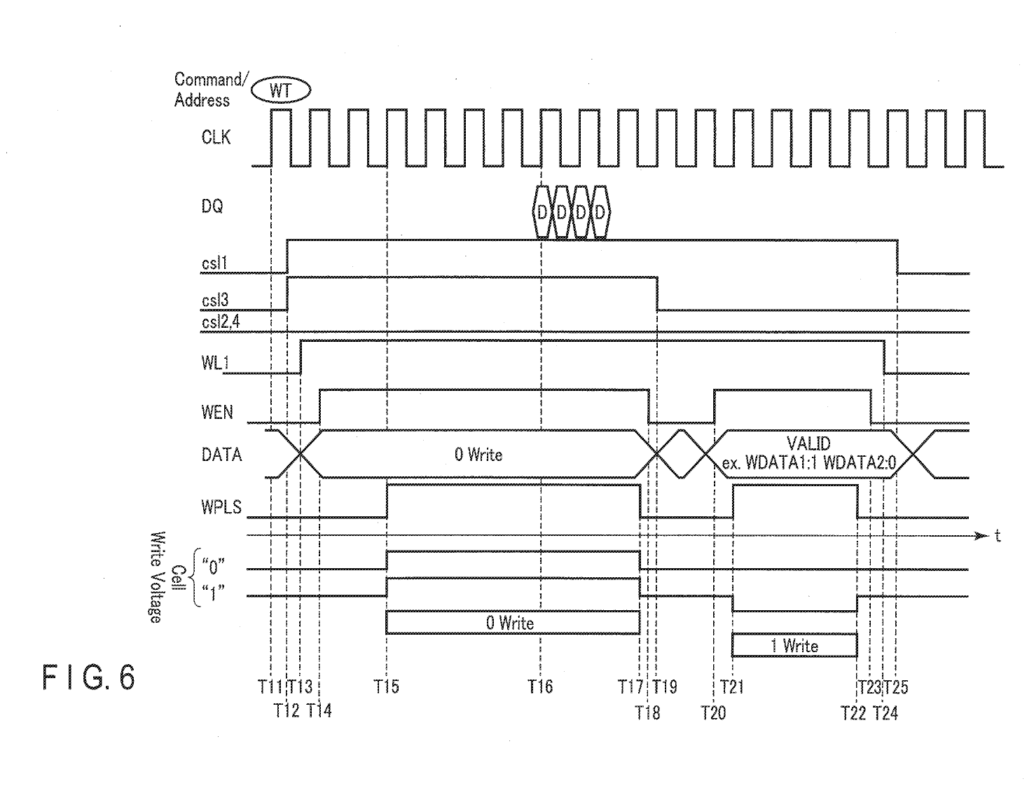

Details of the writing performed in the first embodiment will be described with reference to FIG. 6.

FIG. 6 is a timing chart illustrating the operation of writing 1 data and 0 data in memory cells MC_A and MC_C, respectively, which memory cells are included among memory cells MC_A, MC_B, MC_C and MC_D shown in FIG. 3. In FIG. 6, the states of signals are indicated along the time axis.

The operation shown in FIG. 6 is started when the semiconductor memory device 1 receives a write command WT after it receives an active command (not shown).

Clock CLK, signals CA0 to CA9, data DQ and data strobe signal DQS are supplied from the memory controller 2 to the interface 10. Signals CA0 to CA9 include a column address and a command. A description of data strobe signal DQS will be omitted herein.

First of all, a row address is received simultaneous with an active command. After the reception of the active command, a write command WT is received at time T11. A column address is received simultaneous with the write command WT. A write-target column is selected based on the received row address and column address.

To be more specific, the row address and the column address are supplied to decoders 12A and 12B. Decoders 12A and 12B decode the row address and select a word line. Decoder 12A decodes the column address and makes write-target column selection signals csl1 and csl3 active. In other words, column selection signals csl1 and csl3 are set at “H.” Decoder 12B decodes the column address and makes write-target column selection signal cslb1 active. In other words, column selection signal cslb1 is set at “H.”

Column selection signals csl1 and csl3 output from decoder 12A are supplied to column selector 17A by way of write controller 15A and write driver 16A. At time T12, column selector 17A selects bit lines BL1 and BL3 by setting column selection signals csl1 and csl3 at “H.” Column selection signals csl2 and csl4 are kept at “L” then.

Column selection signal cslb1 output from decoder 12B is supplied to column selector 17B by way of write controller 15B and write driver 16B. At time T12, column selector 17B selects common source bit line CSBL1 (including the source bit line SBL1) by setting column selection signal cslb1 at “H.” Column selection signal cslb2 is kept at “L” then.

At time T13, a word line driver (not shown) makes word line WL1 active based on a row address. In other words, word line WL1 is set at “H.”

At time T14, the controller 22 makes write enable signal WEN active. In other words, the write enable signal WEN is set at “H.” As a result, a write voltage becomes applicable to write-target memory cell MC.

At time T15, the controller 22 makes write pulse WPLS active. In other words, write pulse WPLS is set at “H.” As a result, 0 data is written in write-target memory cells MC_A and MC_C. In other words, the operation of writing 0 data in memory cells MC_A and MC_C is started after the input of write command WT and before the input of write data, e.g., 3 clocks after the input of write command WT. In the operation of writing 0 data, write driver 16A applies a write voltage Vwt to selection bit lines BL1 and BL3, and write driver 16B applies voltage VSS to selection source bit line SBL1.

Thereafter, at time T16, the reception of write data is started. The operation of writing 0 data in memory cells MC_A and MC_C is executed after the reception of write data and is ended at time T17. Thereafter, at time T18, write enable signal WEN is made inactive (“L”). At time T19, column selection signal csl3 is made inactive (“L”), and bit line BL3 is made unselected.

Thereafter, at time T20, the controller 22 makes write enable signal WEN active (“H”) again. As a result, a write voltage becomes applicable to write-target memory cell MC. At time T21, write pulse WPLS is made active (“H”). As a result, the operation of writing 1 data only in write-target memory cell MC_A is started. Since memory cell MC_C is not selected because of the inactive state (“L”) of column selection signal csl3, the operation of writing 1 data in memory cell MC_C is not executed. In the operation of writing 1 data, write driver 16B applies a write voltage Vwt to selection source bit line SBL1, and write driver 16A applies voltage VSS to selection bit line BL1.

Subsequently, at time T22, write pulse WPLS is made inactive (“L”), and the operation of writing 1 data in memory cell MC_A is ended. Thereafter, at time T23, write enable signal WEN is made inactive (“L”). At time T24, word line WL1 is made inactive (“L”), and at time T25, column selection signal csl1 is made inactive (“L”). In the above-mentioned manner, the write operation is ended.

### [1-3] Advantages of First Embodiment

The semiconductor memory device of the first embodiment is advantageous in that a high write success rate can be maintained in the writing, and the write time can be shortened, accordingly.

A detailed description will be given of the advantage of the present embodiment.

A writing using the spin transfer torque magnetization reversal method (spin transfer torque writing) is known as applicable to the writing performed for memory cell MV having an MTJ element. In the spin transfer torque writing, the resistance state of the MTJ element is transitioned by changing the magnetization direction of a recording layer by spin transfer torque. In the spin transfer torque writing, the magnetization reversal of the recording layer occurs by supplying a current having more than a predetermined value to the MTJ element. By changing the direction in which the current flows through the MTJ element, the magnetizations of a recording layer and a reference layer are changed from the parallel state to the anti-parallel state, or from the anti-parallel state to the parallel state. When the magnetization of the recording layer and the magnetization of the reference layer are in the parallel state, the MTJ element is in the low resistance state (e.g., 0 data). When the magnetization of the recording layer and the magnetization of the reference layer are in the anti-parallel state, the MTJ element is in the high resistance state (e.g., 1 data).

Since the magnetization reversal by spin transfer torque is a Poisson process executed by the aid of the thermal energy of a room temperature, namely, a phonon, the magnetization reversal is essentially a probabilistic phenomenon. Therefore, the write current Ic for the magnetization reversal varies under the influence of the phonon each time the write current Ic is supplied. The variation is dependent on the magnetization reversal process and the pulse width of the current to be supplied. It is thought that the probability of the magnetization reversal of the MTJ element by the spin transfer torque can be represented as a simple thermal activity process, such as that indicated by formula (1) set forth below. (See, for example, Z. Li and S. Zhang, Physical Review B, Vol. 69, 134416 (2004)).

$$P ( τ ) = 1 - exp [ - τ / {τ}_{0} exp \{ - \frac{Δ {E}_{a}}{{k}_{B} T} ( 1 - \frac{I}{{I}_{c 0}} ) \} ] \qquad ( 1 )$$

where τ(sec) is a pulse width of a current, To is a quantity referred to as an attempt time and is normally 1 nsec, ΔEa is anisotropic energy of the recording layer, ΔEa/k_{B}T represents a thermal stability of the recording layer, I[A] is a value of a current to be supplied, and I_{c0}[A] is an inversion current at the absolute zero temperature.

Let us assume that the writing is performed for memory cell MC by application of a write current. If 0 data and 1 data are written using constant voltages opposite in polarity as write voltages, a write circuit for applying the write voltages can be a simple circuit, and the write control is easy to perform.

Where constant voltages opposite in polarity are applied for the writing, the current flowing in the writing (0 writing) from the high resistance state to the low resistance state is smaller than the current flowing in the writing (1 writing) from the low resistance state to the high resistance state.

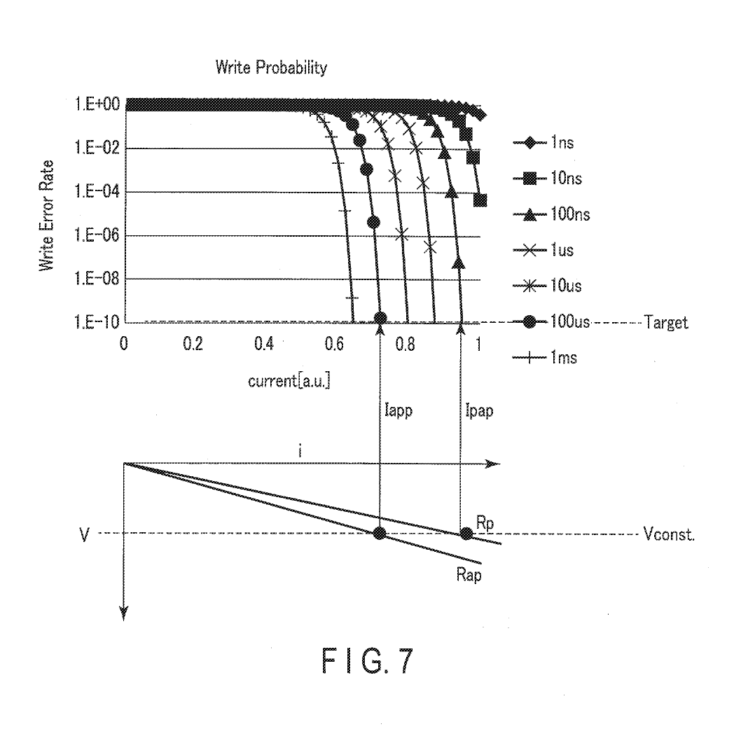

FIG. 7 illustrates how the write error rate and the write current are related when the write time is used as a parameter. Where I and I_{c0} are substantially equal between the 0 writing and the 1 writing, and the writing is performed by application of constant voltages, current Iapp flowing in the 0 writing is smaller than current Ipap flowing in the 1 writing, as can be seen from FIG. 7. In order to permit the write error rate in the 0 writing to be equal to the write error rate in the 1 writing, the write time in the 0 writing is longer than the write time in the 1 writing.

In the present embodiment, therefore, the 0 writing is started after the input of a write command and before the start of the reception of write data, and the 1 writing is started after the end of the reception of the write data. In this manner, the 0 writing, which requires a longer write time than the 1 writing, is started before the 1 writing is started. By so doing, the write time can be shortened, while simultaneously maintaining high write success rates (or low write error rates) in both the 0 writing and the 1 writing.

### [2] Second Embodiment

In the second embodiment, the writing of 0 data and the writing of 1 data are ended substantially at the same time. In the following, a description will be given mainly of the features differentiating the second embodiment from the first embodiment.

### [2-1] Configuration of Semiconductor Memory Device

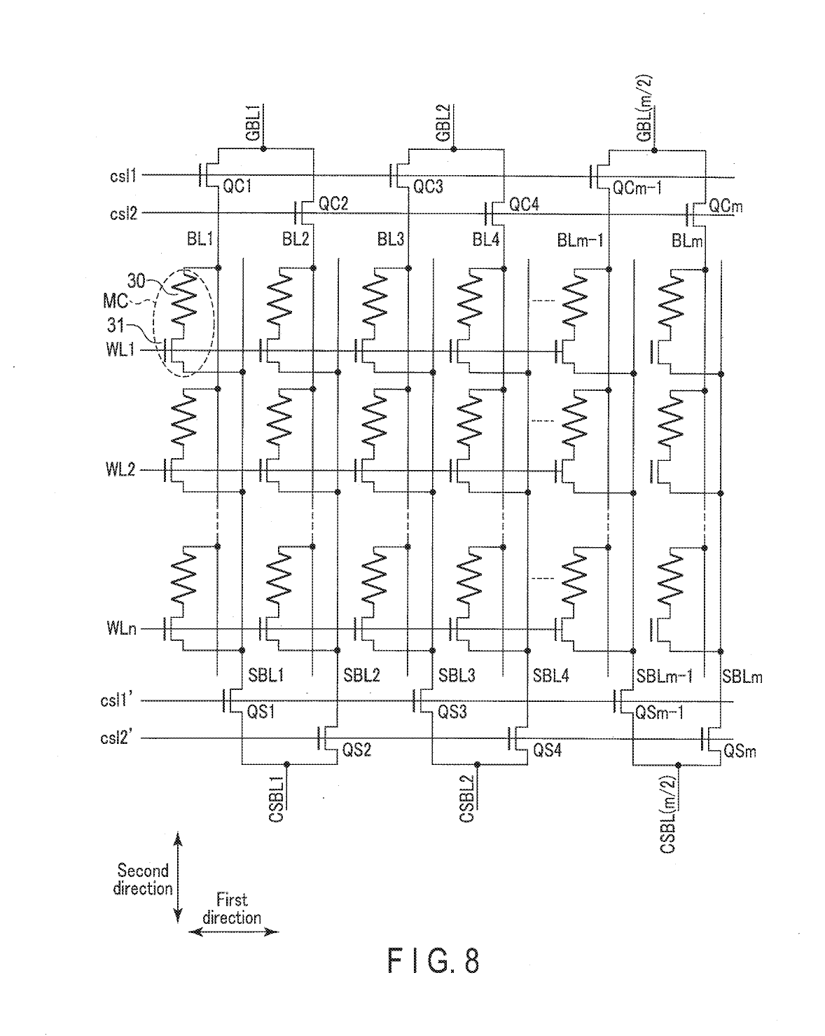

The function blocks of the second embodiment are similar to those of the first embodiment shown in FIG. 1. The cell array 11 of the semiconductor memory device 1 of the second embodiment will be described in detail with reference to FIG. 8. FIG. 8 illustrates the elements and connections of the cell array 11 of the second embodiment.

The cell array 11 comprises n word lines WL (WL1 to WLn), m bit lines BL (BL1 to BLm) and m source bit lines SBL (SBL1 to SBLm). The symbols n and m are natural numbers not less than 1.

The bit lines BL1, BL2, . . . , BLm are arranged in a first direction. The word lines WL1, WL2, . . . , WLn are arranged in a second direction so that they intersect the bit lines BL (for example, at right angles to each other). The source bit lines SBL1, SBL2, . . . , SBLm are arranged in the first direction so that they intersect the word lines WL (for example, at right angles to each other).

Bit lines BL1 and BL2 are connected to global bit line GBL1 by way of nMOS transistors QC1 and QC2, respectively. Bit lines BL3 and BL4 are connected to global bit line GBL2 by way of nMOS transistors QC3 and QC4, respectively.

Likewise, bit lines BLm−1 and BLm are connected to global bit line GBL(m/2) by way of nMOS transistors QCm−1 and QCm, respectively. Column selection signal csl1 is supplied to the gates of nMOS transistors QC1, QC3, . . . , QCm−1. Column selection signal csl2 is supplied to the gates of nMOS transistors QC2, QC4, . . . , QCm.

Source bit lines SBL1 and SBL2 are connected to common source bit line CSBL1 by way of nMOS transistors QS1 and QS2, respectively. Source bit lines SBL3 and SBL4 are connected to common source bit line CSBL2 by way of nMOS transistors QS3 and QS4, respectively. Likewise, source bit lines SBLm−1 and SBLm are connected to common source bit line CSBL(m/2) by way of nMOS transistors QSm−1 and QSm, respectively. Column selection signal csl1′ is supplied to the gates of nMOS transistors QS1, QS3, . . . , QSm−1. Column selection signal csl2′ is supplied to the gates of nMOS transistors QS2, QS4, . . . , QSm.

Memory cells MC of one row are connected to one word line WL, and memory cells MC of one column are connected to one pair formed by one bit line BL and one source bit line SBL. Each memory cell MC is arranged at the position where word line WL intersects bit line BL and source bit line SBL.

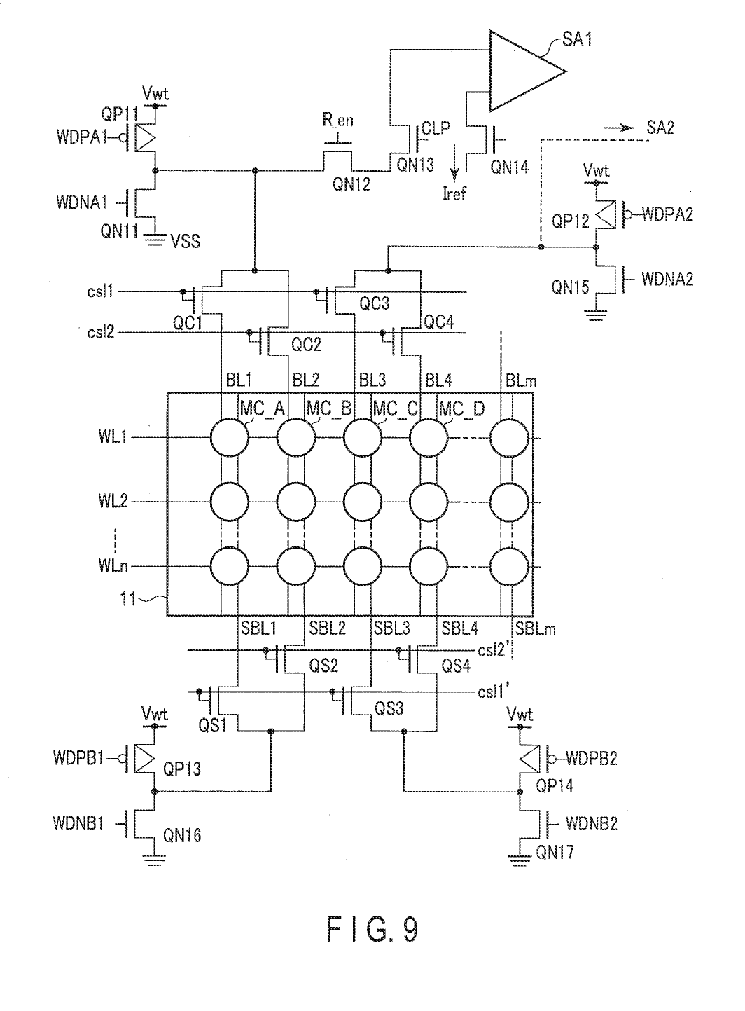

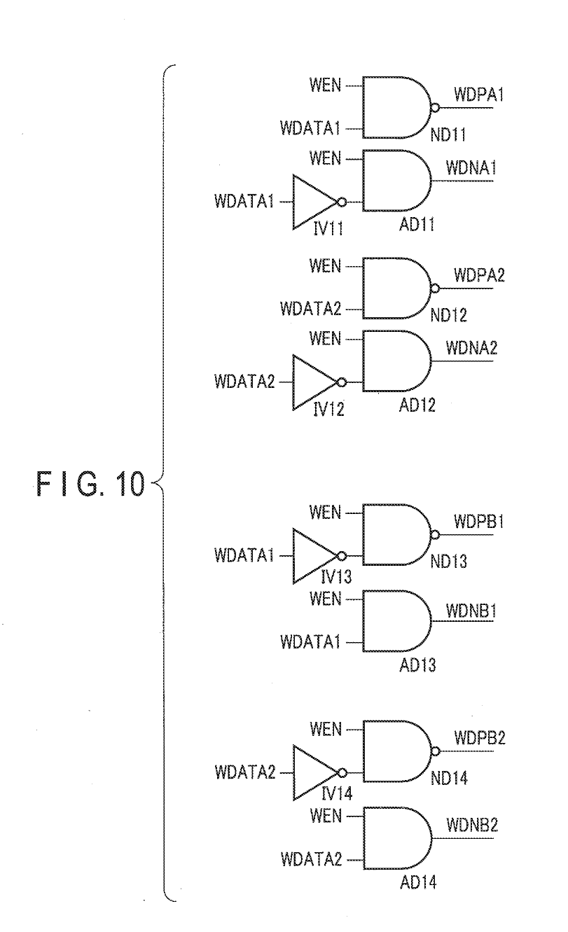

FIGS. 9 and 10 illustrate a configuration of a write circuit including the cell array and write driver of the second embodiment.

In the following, a description will be given of the elements and connections provided on the side of bit line BL.

As shown in FIG. 10, NAND circuit ND11 receives write data WDATA1 accompanying a write command and a write enable signal WEN, and outputs an inverted signal of write data WDATA1 as signal WDPA1 when the write enable signal WEN is at “H.”

Inverter IV11 receives write data WDATA1, and outputs an inverted signal obtained by inverting the received write data WDATA1. AND circuit AD11 receives the inverted signal and write enable signal WEN, and outputs the inverted signal as signal WDNA1 when the write enable signal WEN is at “H.”

NAND circuit ND12 receives write data WDATA2 accompanying a write command and a write enable signal WEN, and outputs an inverted signal of write data WDATA2 as signal WDPA2 when the write enable signal WEN is at “H.”

Inverter IV12 receives write data WDATA2, and outputs an inverted signal obtained by inverting the received write data WDATA2. AND circuit AD12 receives the inverted signal and write enable signal WEN, and outputs the inverted signal as signal WDNA2 when the write enable signal WEN is at “H.”

As shown in FIG. 9, pMOS transistor QP11 is supplied with signal WDPA1 at the gate and applied with write voltage Vwt at the source. NMOS transistor QN11 is supplied with signal WDNA1 at the gate and applied with reference voltage VSS at the source. The drain of pMOS transistor QP11 and the drain of nMOS transistor QN11 are connected to each other.

The drains of pMOS transistor QP11 and nMOS transistor QN11 are connected to either of the sources and drains of nMOS transistors QC1 and QC2. The other one of the source and drain of nMOS transistor QC1 is connected to bit line BL1. The other one of the source and drain of nMOS transistor QC2 is connected to bit line BL2.

The drain of nMOS transistor QN13 is connected to the first terminal of sense amplifier SA1, and the source of nMOS transistor QN13 is connected, by way of nMOS transistor QN12, to the sources or drains of nMOS transistors QC1 and QC2. Read enable signal R_en is supplied to the gate of nMOS transistor QN12, and clamp signal CLP is supplied to the gate of nMOS transistor QN13. The second terminal of sense amplifier SA1 is supplied with current Iref flowing through nMOS transistor QN14.

PMOS transistor QP12 is supplied with signal WDPA2 at the gate and applied with write voltage Vwt at the source. NMOS transistor QN15 is supplied with signal WDNA2 at the gate and applied with reference voltage VSS at the source. The drain of pMOS transistor QP12 and the drain of nMOS transistor QN15 are connected to each other.

The drains of pMOS transistor QP12 and nMOS transistor QN15 are connected to either of the sources and drains of nMOS transistors QC3 and QC4. The other one of the source and drain of nMOS transistor QC3 is connected to bit line BL3. The other one of the source and drain of nMOS transistor QC4 is connected to bit line BL4.

Bit lines BLm−1 and BLm have elements similar to bit lines BL1 and BL2 or bit lines BL3 and BL4, and are connected in a similar manner to that of bit lines BL1 and BL2 or bit lines BL3 and BL4. NMOS transistors QCm−1 and QCm are connected to bit lines BLm−1 and BLm, respectively.

Column selection signal csl1 is supplied to the gates of nMOS transistors QC1, QC3, . . . , QCm−1. Column selection signal csl2 is supplied to the gates of nMOS transistors QC2, QC4, . . . , QCm.

Next, a description will be given of the elements and connections provided on the side of source bit line SBL.

As shown in FIG. 10, inverter IV13 receives write data WDATA1, and outputs an inverted signal obtained by inverting the received write data WDATA1. NAND circuit ND13 receives the inverted signal and write enable signal WEN, and outputs write data WDATA1 as signal WDPB1 when the write enable signal WEN is at “H.” AND circuit AD13 receives write data WDATA1 and write enable signal WEN, and outputs write data WDATA1 as signal WDNB1 when the write enable signal WEN is at “H.”

In the meantime, inverter IV14 receives write data WDATA2, and outputs an inverted signal obtained by inverting the received write data WDATA2. NAND circuit ND14 receives the inverted signal and write enable signal WEN, and outputs write data WDATA2 as signal WDPB2 when the write enable signal WEN is at “H.” AND circuit AD14 receives write data WDATA2 and write enable signal WEN, and outputs write data WDATA2 as signal WDNB2 when the write enable signal WEN is at “H.”

As shown in FIG. 9, pMOS transistor QP13 is supplied with signal WDPB1 at the gate and applied with write voltage Vwt at the source. NMOS transistor QN16 is supplied with signal WDNB1 at the gate and applied with reference voltage VSS at the source. The drain of pMOS transistor QP13 and the drain of nMOS transistor QN16 are connected to each other.

The drains of pMOS transistor QP13 and nMOS transistor QN16 are connected to either of the sources and drains of nMOS transistors QS1 and QS2. The other one of the source and drain of nMOS transistor QS1 is connected to source bit line SBL1. The other one of the source and drain of nMOS transistor QS2 is connected to source bit line SBL2.

PMOS transistor QP14 is supplied with signal WDPB2 at the gate and applied with write voltage Vwt at the source. NMOS transistor QN17 is supplied with signal WDNB2 at the gate and applied with reference voltage VSS at the source. The drain of pMOS transistor QP14 and the drain of nMOS transistor QN17 are connected to each other.

The drains of pMOS transistor QP14 and nMOS transistor QN17 are connected to either of the sources and drains of nMOS transistors QS3 and QS4. The other one of the source and drain of nMOS transistor QS3 is connected to source bit line SBL3. The other one of the source and drain of nMOS transistor QS4 is connected to source bit line SBL4.

Source bit lines SBLm−1 and SBLm have elements similar to source bit lines SBL1 and SBL2 or source bit lines SBL3 and SBL4, and are connected in a similar manner to that of source bit lines SBL1 and SBL2 or source bit lines SBL3 and SBL4. NMOS transistors QSm−1 and QSm are connected to source bit lines SBLm−1 and SBLm, respectively.

Column selection signal csl1′ is supplied to the gates of nMOS transistors QS1, QS3, . . . , QSm−1. Column selection signal csl2′ is supplied to the gates of nMOS transistors QS2, QS4, . . . , QSm.

### [2-2] Write Operation of Semiconductor Memory Device

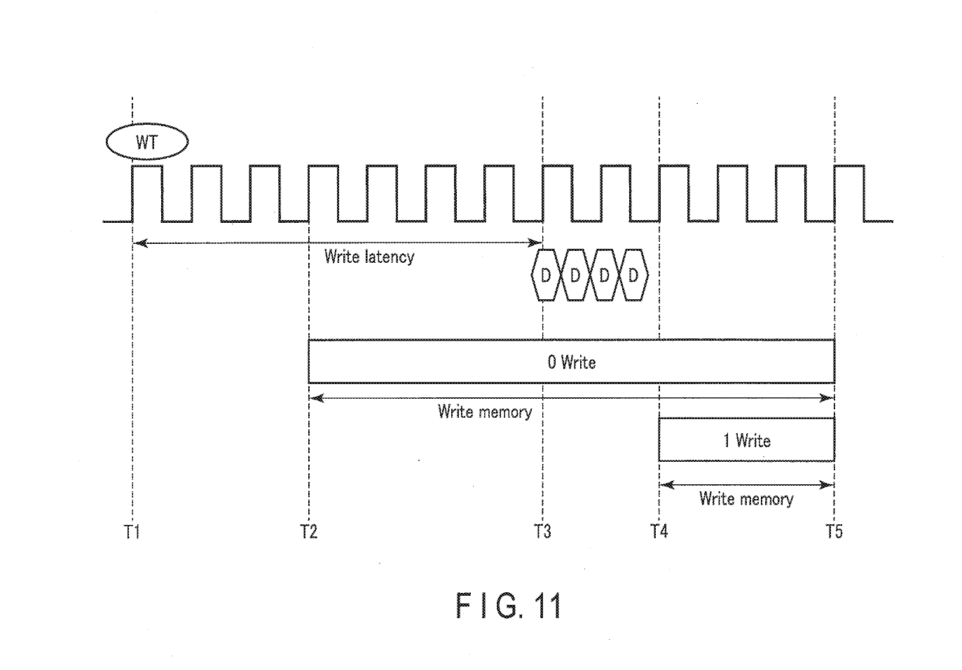

An outline of a write operation performed in the second embodiment will be described with reference to FIG. 11. FIG. 11 is a timing chart illustrating the writing performed by the semiconductor memory device of the second embodiment.

After the reception of write command WT at time T1, the semiconductor memory device 1 is kept on standby for write latency WL (corresponding to seven clocks), and receives write data accompanying the write command at time T3. The write latency (corresponding to seven clocks) is an example and varies in accordance with a clock frequency.

At time T2, which is after the reception of the write command WT at time T1 and before the reception of the write data at time T3, the writing of 0 data is started. For example, the writing of 0 data is started immediately after the reception of the write command WT at time T1, or at time T2 which is 3 clocks after the reception of the write command WT.

At time T3, the reception of write data is started, and the writing of 1 data is started at time T4 after all the write data is received. Thereafter, at time T5, the writing of 0 data and 1 data is ended.

In the writing of 0 data performed from time T2 to T4, 0 data is written in all the memory cells MC designated by an address received along with a write command WT, as in the first embodiment. In the writing of 1 data performed from time T4 to time T5, 1 data is written only in the memory cells MC where it should be written, based on the received write data. In the writing of 1 data performed from time T4 to time T5, 0 data is written in the memory cells MC other than the memory cells where 1 data should be written.

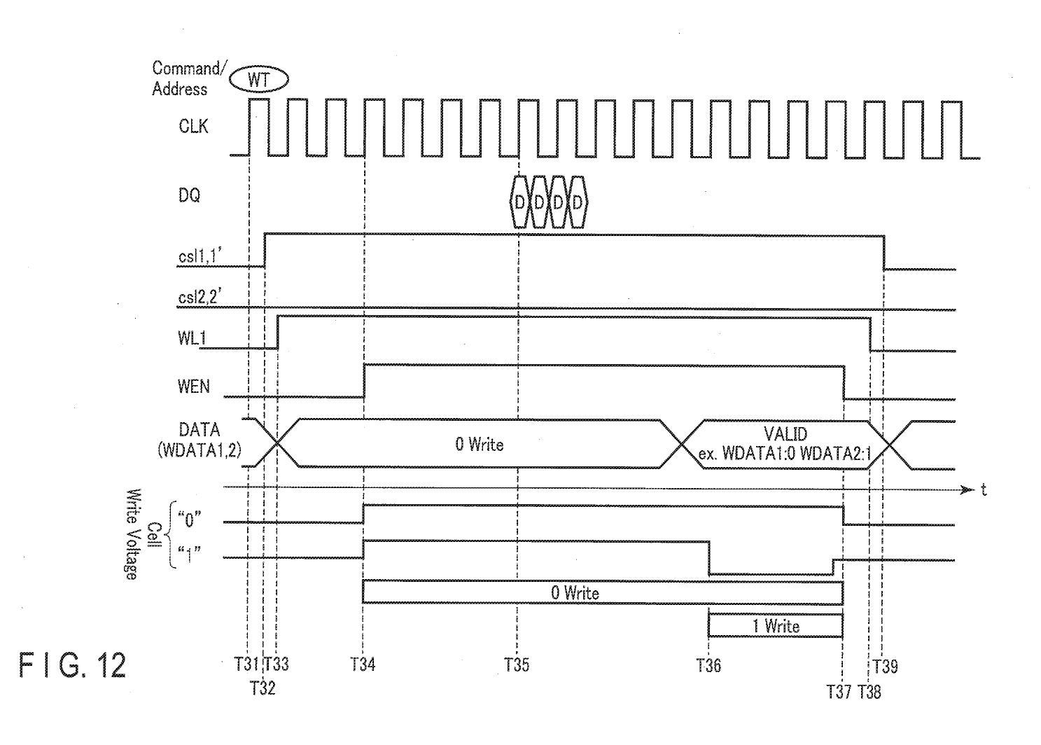

Details of the writing performed in the second embodiment will be described with reference to FIG. 12. FIG. 12 is a timing chart illustrating the operation of writing 1 data and 0 data in memory cells MC_A and MC_C shown in FIG. 9, respectively. In FIG. 12, the states of signals are indicated along the time axis.

The operation shown in FIG. 12 is started when the semiconductor memory device 1 receives a write command WT after it receives an active command (not shown).

Clock CLK, signals CA0 to CA9, data DQ and data strobe signal DQS are supplied from the memory controller 2 to the interface 10. Signals CA0 to CA9 include a column address and a command. A description of data strobe signal DQS will be omitted herein.

A row address is received simultaneous with an active command. After the reception of the active command, a write command WT is received at time T31. A column address is received simultaneous with the write command WT. A write-target column is selected based on the received row address and column address.

To be more specific, the row address and the column address are supplied to decoders 12A and 12B. Decoders 12A and 12B decode the row address and select a word line. Decoder 12A decodes the column address and makes column selection signal csl1 for selecting a write-target column active. In other words, column selection signal csl1 is set at “H.” Decoder 12B decodes the column address and makes column selection signal csl1′ for selecting a write-target column active. In other words, column selection signal csl1′ is set at “H.”

Column selection signal csl1 output from decoder 12A is supplied to column selector 17A by way of write controller 15A and write driver 16A. At time T32, column selector 17A selects bit lines BL1 and BL3 by setting column selection signal csl1 at “H.” Column selection signal csl2 is kept at “L” then.

Column selection signal csl1′ output from decoder 12B is supplied to column selector 17B by way of write controller 15B and write driver 16B. At time T32, column selector 17B selects source bit lines SBL1 and SBL3 by setting column selection signal csl1′ at “H.” Column selection signal csl2′ is kept at “L” then.

At time T33, a word line driver (not shown) makes word line WL1 active based on a row address. In other words, word line WL1 is set at “H.”

Thereafter, at time T34, the controller 22 makes write enable signal WEN active (“H”). As a result, 0 data is written in write-target memory cells MC_A and MC_C. In other words, the operation of writing 0 data in memory cells MC_A and MC_C is started after the input of write command WT and before the input of write data, e.g., 3 clocks after the input of write command WT. In the operation of writing 0 data, write driver 16A applies write voltage Vwt to selection bit lines BL1 and BL3, and write driver 16B applies voltage VSS to selection source bit lines SBL1 and SBL3.

Thereafter, at time T35, the reception of write data is started. After the write data is received, the operation of writing 1 data in write-target memory cell MC_A is started at time T36, and the operation of writing 1 data ends at time T37. The writing of 0 data started at time T36 is performed only for memory cell MC_C. At time T37, write enable signal WEN is made inactive (“L”), and the writing of 0 data ends, simultaneous with the end of the writing of 1 data. In the writing of 1 data, write driver 16B applies a write voltage Vwt to selection bit line SBL1, and write driver 16A applies voltage VSS to selection source bit line BL1.

At time T38, word line WL1 is made inactive (“L”), and at time T39, column selection signals csl1 and csl1′ are made inactive (“L”). In the above-mentioned manner, the writing is ended.

### [2-3] Advantages of Second Embodiment

Like the semiconductor memory device of the first embodiment, the semiconductor memory device of the second embodiment is advantageous in that a high write success rate can be maintained in the writing, and the write time can be shortened, accordingly.

In addition, the second embodiment enables the 0 data write time to be longer than that of the first embodiment, and the write success rate in the writing of 0 data can be stably kept at a higher value than that of the first embodiment. Furthermore, the writing of 0 data and the writing of 1 data end substantially at the same time. The writing is therefore easy to control. The other advantages of the second embodiment are similar to those of the first embodiment.

Although the writing of 0 data and the writing of 1 data are ended substantially at the same time in the second embodiment, this is not restrictive. The writing of 0 data may be ended during the writing of 1 data.

### [3] Third Embodiment

In the third embodiment, a sense amplifier is employed to apply a write voltage to bit lines BL. In the following, a description will be given mainly of the features differentiating the third embodiment from the second embodiment.

### [3-1] Configuration of Semiconductor Memory Device

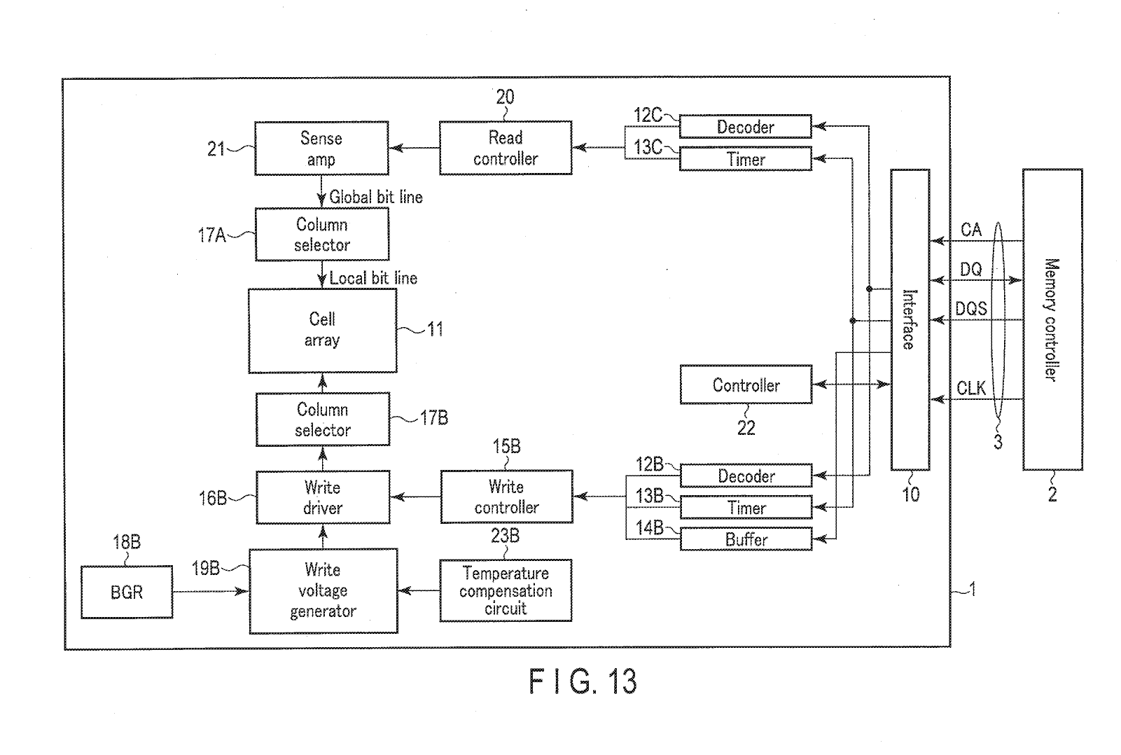

FIG. 13 illustrates function blocks of a semiconductor memory device according to the third embodiment and a memory controller.

The semiconductor memory device 1 comprises elements for driving the bit lines connected to the first end of a memory cell, namely, decoder 12C, timer 13C, a read controller 20, a sense amplifier 21 and column selector 17A. The configuration for driving the source bit lines connected to the second terminal of the memory cell is similar to the configuration shown in FIG. 1.

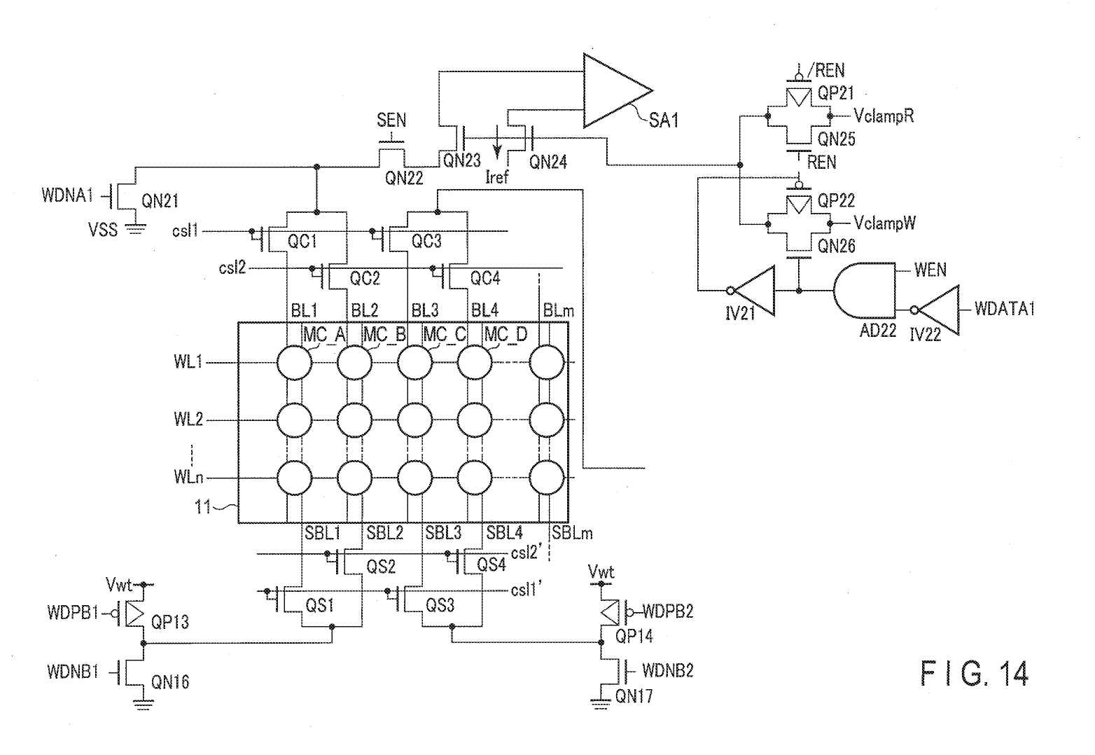

FIGS. 14 and 15 illustrate a configuration of a write circuit including the cell array and write driver of the third embodiment.

In the following, a description will be given of the elements and connections provided on the side of bit line BL.

As shown in FIG. 15, AND circuit AD21 receives write data WDATA1 accompanying a write command and a write enable signal WEN, and outputs write data WDATA1 as signal WDNA1 when the write enable signal WEN is at “H.”

As shown in FIG. 14, nMOS transistor QN21 is supplied with signal WDNA1 at the gate and applied with reference voltage VSS at the source. The drain of nMOS transistor QN21 is connected to the sources or drains of nMOS transistors QC1 and QC2.

The drain of nMOS transistor QN23 is connected to the first terminal of sense amplifier SA1, and the source of nMOS transistor QN23 is connected, by way of nMOS transistor QN22, to the sources or drains of nMOS transistors QC1 and QC2. Signal SEN is supplied to the gate of nMOS transistor QN22. The second terminal of sense amplifier SA1 is supplied with current Iref flowing through nMOS transistor QN24.

Signal VclampR is supplied to the input terminal of the pass transistors made up of pMOS transistor QP21 and nMOS transistor QN25, and signal VclampW is supplied to the input terminal of the pass transistors made up of pMOS transistor QP22 and nMOS transistor QN26. Outputs of these pass transistors are supplied to the gates of nMOS transistors QN23 and QN24. Signal REN is supplied to the gate of nMOS transistor QN25, and signal RENb is supplied to the gate of pMOS transistor QP21.

Inverter IV22 receives write data WDATA1, and outputs an inverted signal obtained by inverting the received write data WDATA1. AND circuit AD22 receives the inverted signal and write enable signal WEN, and supplies the inverted signal to the gate of nMOS transistor QN26 and inverter IV21 when the write enable signal WEN is at “H.” An output of inverter IV21 is supplied to the gate of pMOS transistor QP22. Note that the read enable signal REN and the write enable signal WEN are a complementary signal each other.

As shown in FIG. 15, inverter IV23 receives write data WDATA1, and outputs an inverted signal obtained by inverting the received write data WDATA1. AND circuit AD23 receives the inverted signal and write enable signal WEN, and outputs the inverted signal when the write enable signal WEN is at “H.” OR circuit OR1 receives an output of AND circuit AD3 and signal REN, and outputs signal SEN. Signal SEN is supplied to the gate of nMOS transistor QN22.

As shown in FIG. 15, NAND circuit ND21 receives write data WDATA1 and write enable signal WEN, and outputs write data WDATA1 as signal WDPB1 when the write enable signal WEN is at “H.”

Inverter IV24 receives write data WDATA1, and outputs an inverted signal obtained by inverting the received write data WDATA1. OR circuit OR3 receives the inverted signal and read enable signal REN, and outputs the inverted signal when the read enable signal REN is at “L.” OR circuit OR2 receives write enable signal WEN and read enable signal REN. AND circuit AD24 receives the inverted signal and an output of OR circuit OR2, and outputs the inverted signal as signal WDNB1 when the write enable signal WEN or the read enable signal REN is at “H.”

When 0 data is written in the writing, sense amplifier 21 (SA1, SA2) applies a voltage to selection bit lines BL1 and BL3, and write driver 16B applies voltage VSS to selection source bit lines SBL1 and SBL3. When 1 data is written, write driver 16B applies a write voltage Vwt to selection bit line SBL1, and a driver (nMOS transistor QN21) applies voltage VSS to selection bit line BL1. The other features of the third embodiment are similar to those of the second embodiment.

### [3-2] Advantages of Third Embodiment

Like the semiconductor memory devices of the first and second embodiments, the semiconductor memory device of the third embodiment is advantageous in that a high write success rate can be maintained in the writing, and the write time can be shortened, accordingly.

The third embodiment enables a sense amplifier to be employed for applying a write voltage to bit lines BL of a memory cell. The sense amplifier is a circuit for sensing a current flowing through memory cell MC in reading. Since the sensing amplifier can be used for the writing, the number of elements required for the write circuit can be reduced. The other advantages of the third embodiment are similar to those of the first and second embodiments.

### [4] Modifications

The first to third embodiments employ temperature compensation circuits 23A and 23B for adjusting a write voltage in accordance with a temperature change. A modification of the temperature compensation circuits 23A and 23B of the first to third embodiments will be described.

### [4-1] Temperature Compensation Circuits

As shown in FIGS. 1 and 13, the semiconductor memory device 1 of each of the first to third embodiments comprises temperature compensation circuits 23A and 23B. Temperature compensation circuits 23A and 23B adjust a write voltage in accordance with the temperature of memory cell MC or the ambient temperature of the semiconductor memory device 1 in such a manner as to attain a desired write success rate.

As mentioned above, the probability of the magnetization reversal of the MTJ element by the spin transfer torque writing can be represented by formula (1). Formula (1) can be transformed as follows:

$$I = {I}_{c 0} [ 1 + \frac{{k}_{B} T}{Δ {E}_{a}} log ( - \frac{{τ}_{0}}{τ} log ( 1 - P ( τ ) ) ) ] \qquad ( 2 )$$

where “log” is a natural logarithm.

In formula (2), what is represented by formula (3) is negative.

$$log ( - \frac{{τ}_{0}}{τ} log ( 1 - P ( τ ) ) ) \qquad ( 3 )$$

Let us assume that the voltage applied to memory cell MC in the writing of 0 data is V0, and the voltage applied to memory cell MC in the writing of 1 data is V1. Let us also assume that the reference potential is Vc.

Since the write current I flowing through memory cell MC in the writing is a negative function with respect to a temperature, a large current is required at low temperature. Conversely, the write current may be a small current at high temperature. Where the write error rate is as close as possible to zero, formula (3) takes on a negative value. Therefore, the write current is a negative function with respect to a temperature.

Since the write current I changes in proportion to |Vc-V0| or |V1-Vc|, either |Vc-V0| or |V1-Vc| is used as a negative function with respect to a temperature.

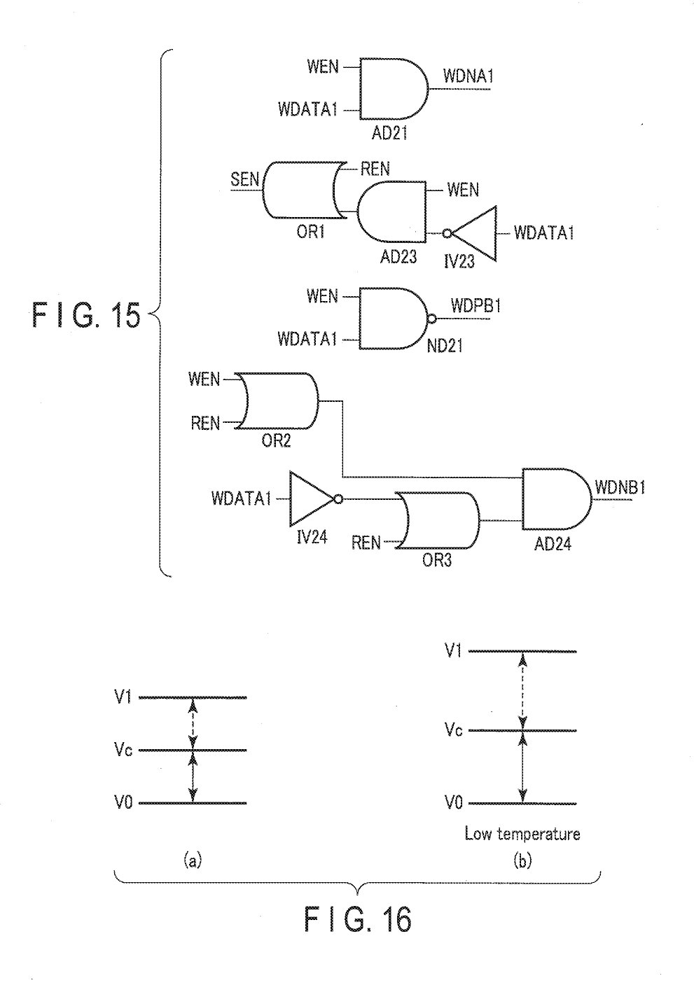

Write voltages which are to be applied when temperature compensation is performed by temperature compensation circuits 23A and 23B will be described with reference to FIGS. 16, 17 and 18.

FIG. 16 illustrates an example of a manner in which temperature compensation is performed for write voltages V0 and V1.

In FIG. 16, (a) illustrates how voltages V0, V1 and Vc are when the temperature of memory cell MC is the room temperature, i.e., before temperature compensation is performed. Voltage V0 and voltage V1 differ from reference potential Vc by the same potential difference. In FIG. 16, (b) illustrates a case where the temperature of memory cell MC is low. When the temperature of memory cell MC is low, a write voltage higher than that applied at room temperature is required. Therefore, voltages V0 and V1 are adjusted by the temperature compensation circuits so that the adjusted voltages are higher than the voltages shown in (a) of FIG. 16.

When the temperature of memory cell MC is high, a write voltage lower than that applied at room temperature suffices. In this case, voltages V0 and V1 are adjusted by the temperature compensation circuits so that the adjusted voltages are lower than the voltages shown in (a) of FIG. 16.

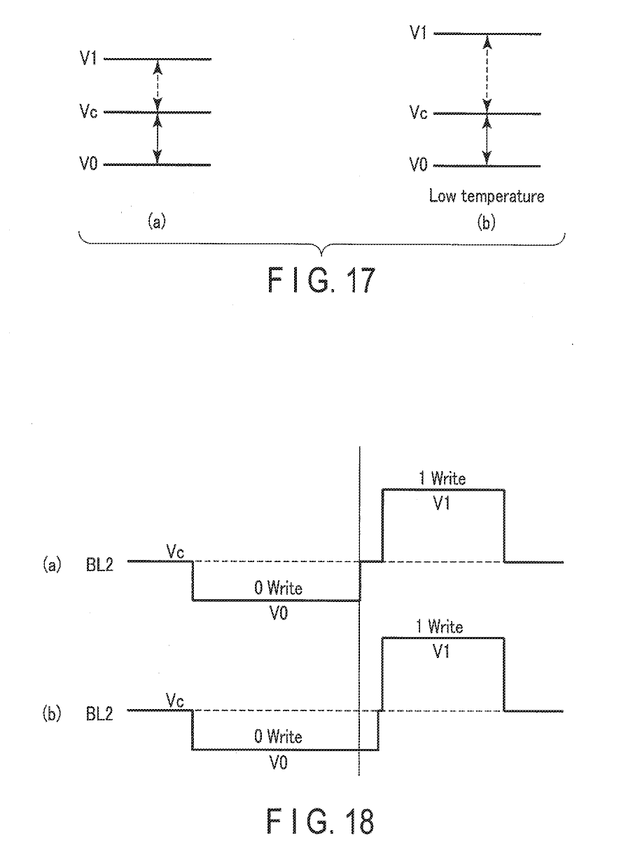

FIG. 17 illustrates another example of a manner in which temperature compensation is performed for write voltages V0 and V1.

In FIG. 17, (a) illustrates how voltages V0, V1 and Vc are when the temperature of memory cell MC is room temperature, i.e., before temperature compensation is performed. Voltage V0, V1 and Vc are similar to those shown in (a) of FIG. 16. That is, voltage V0 and voltage V1 differ from reference potential Vc by the same potential difference. In FIG. 17, (b) illustrates a case where the temperature of memory cell MC is low. When the temperature of memory cell MC is low, voltage V1 is adjusted by the temperature compensation circuits so that the adjusted voltage V1 is higher than the voltage shown in (a) of FIG. 17. On the other hand, voltage V0 is set at the same value as the voltage shown in (a) of FIG. 17.

When the temperature of memory cell MC becomes high, a write voltage lower than that applied at room temperature suffices. In this case, voltage V1 is adjusted by the temperature compensation circuits so that the adjusted voltage is lower than the voltage shown in (a) of FIG. 17. On the other hand, voltage V0 is set at the same value as the voltage shown in (a) of FIG. 17.

FIG. 18 illustrates another example of a manner in which temperature compensation is performed for write voltages V0 and V1.

In FIG. 18, (a) and (b) illustrate voltages V0 and V1 that are applied to bit line BL2 when temperature compensation is performed. In (a) of FIG. 18, voltage V1 is set higher than V0 by the temperature compensation circuits. In (b) of FIG. 18, the pulse width of voltage V0 is set to be long by the temperature compensation circuits. In other words, the application time of voltage V0 is set to be long. Temperature compensation circuits are often used in a read circuit and are compatible with the generation of signal VclampR and signal VclampW. The read circuit of the third embodiment (including a sense amplifier) can be configured as a constant-current write power source having a temperature compensation function.

### [4-2] Advantages of Modification

Temperature compensation circuits 23A and 23B of the modification adjust a write voltage applied to memory cell in accordance with a temperature variation of memory cell MC or a variation in the ambient temperature of the semiconductor memory device 1. As a result, the write success rate is independent of a temperature variation. The other advantages of the modification are similar to those of the first to third embodiments.

While certain embodiments have been described, these embodiments have been presented by way of example only, and are not intended to limit the scope of the embodiments. Indeed, the novel methods and systems described herein may be embodied in a variety of other forms; furthermore, various omissions, substitutions, and changes in the form of the methods and systems described herein may be made without departing from the spirit of the embodiments. The accompanying claims and their equivalents are intended to cover such forms or modifications as would fall within the scope and spirit of the embodiments.

What is claimed is:

1. A semiconductor memory device comprising:
a memory cell including a variable resistance element; and
a first circuit which performs writing for the memory cell,
wherein the first circuit starts writing first data before the first circuit receives write data including the first data and second data, and starts writing the second data after the first circuit receives the write data.

2. The semiconductor memory device according to claim 1, wherein the writing of the first data is started after the write command is received and before a write latency ends.

3. The semiconductor memory device according to claim 1, wherein the writing of the first data is ended before the writing of the second data started.

4. The semiconductor memory device according to claim 1, wherein the writing of the first data is ended after the write data is received, and the writing of the second data is started after the writing of the first data is started.

5. The semiconductor memory device according to claim 1, wherein the writing of the first data and the writing of the second data are ended simultaneously.

6. The semiconductor memory device according to claim 1, wherein the memory cell is applied with a first voltage during the writing of the first data, and is applied with a voltage different in polarity from the first voltage during the writing of the second data.

7. The semiconductor memory device according to claim 1, further comprising:
a first write driver which applies a first voltage to a first wiring connected to the memory cell, during the writing of the first data or the second data; and
a second write driver which applies a second voltage to a second wiring connected to the memory cell, during the writing of the first data or the second data.

8. The semiconductor memory device according to claim 1, further comprising:
a sense amplifier which applies a first voltage to a first wiring connected to the memory cell, during the writing of the first data; and
a write driver which applies a second voltage to a second wiring connected to the memory cell, during the writing of the first data,
wherein the sense amplifier senses a current flowing through the memory cell, when data is read from the memory cell.

9. The semiconductor memory device according to claim 1, further comprising:
a sense amplifier which applies a first voltage to a first wiring connected to the memory cell, during the writing of the first data; and
a write driver which supplies a first current to a second wiring connected to the memory cell,
wherein the sense amplifier senses a current flowing through the memory cell, when data is read from the memory cell.

10. The semiconductor memory device according to claim 1, wherein the memory cell transitions from a high resistance state to a low resistance state when the first data is written, and transitions from the low resistance state to the high resistance state when the second data is written.

11. The semiconductor memory device according to claim 1, wherein the writing of the first data is performed for all memory cells designated by a write-target address, and
the writing of the second data is performed for memory cells where the second data should be written based on the write data.

12. The semiconductor memory device according to claim 1, wherein a write error probability in the writing of the first data and a write error probability in the writing of the second data are controlled by different write currents and different write times.

13. The semiconductor memory device according to claim 1, wherein a write time of the first data is longer than a write time of the second data.

14. The semiconductor memory device according to claim 1, wherein a voltage applied to the memory cell is varied in accordance with a temperature of the memory cell, during the writing of the first data and/or the writing of the second data.

15. The semiconductor memory device according to claim 7, further comprising:
a first voltage generator which applies the first voltage to the first write driver;
a second voltage generator which applies the second voltage to the second write driver; and
a reference circuit which applies a reference voltage to the first and second voltage generators.

16. The semiconductor memory device according to claim 15, further comprising:
a temperature compensation circuit which adjusts the first and second voltages in accordance with a temperature of the memory cell.

17. The semiconductor memory device according to claim 1, wherein the variable resistance element includes a magnetic tunnel junction (MTJ) element.

18. The semiconductor memory device according to claim 17, wherein the semiconductor memory device includes a magnetoresistive random access memory (MRAM).
